(19) United States
(12) Patent Application Publication
(10) Pub. No.: US 2008/0258263 A1
(43) Pub. Date: Oct. 23, 2008

(54) High Current Steering ESD Protection Zener Diode And Method

(76) Inventors: Harry Yue Gee, Sunnyvale, CA (US); Adam J. Whitworth, Los Altos, CA (US); Umesh Sharma, Santa Clara, CA (US)

Correspondence Address: PILLSBURY WINTHROP SHAW PITTMAN LLP, P.O. BOX 10500, MCLEAN, VA, 22102, US

(21) Appl. No.: 11/738,176

(22) Filed: Apr. 20, 2007

(51) Int. Cl. H01L 29/866; G05F 1/00; H01L 21/20

(52) U.S. Cl. 257/605; 327/194; 438/380; 257/E29.335; 257/E21.35

(57) ABSTRACT

A method of fabricating a N+/P+ zener diode where the reverse breakdown occurs in a controlled, and uniform manner leading to improved speed of operation and increase in current handling capability.

### FIELD OF THE INVENTION

The present invention relates to an N+/P+ zener diode where the implanted regions are designed to steer the current flow away from the sidewalls of the diode and more toward the bottom walls in order to induce uniform reverse breakdown leading to improved speed of operation and increase in current handling capability.

### BACKGROUND OF THE INVENTION

MOS devices are susceptible to damage from electrostatic discharge, or ESD. While numerous techniques have been developed to protect MOS devices, there has been a need for an ESD-protection device and method which could be fabricated through simple semiconductor manufacturing techniques.

One such known ESD-protection device is illustrated in FIGS. 1 and 2. As shown in FIG. 1, a conventional P type substrate 100 is provided, with an epitaxial layer 110 of P-material formed thereon in a conventional manner. Using CMOS fabrication techniques, a P type implant 120 is formed into and through the epitaxial layer 110 until the implanted region electrically contacts the substrate 100. Using conventional techniques, an N+ deposition 130 is formed within the P-implanted region 120. By reverse biasing the junction of the N+ implant 130 and the P implanted region, a depletion layer 140 is formed, which is represented electrically as a capacitor 210 in parallel with the N+ IP zener diode 220 in FIG. 2. The composite structure protects the internal circuitry from ESD discharge by providing a low resistance path to ground during an ESD event.

While the device of FIGS. 1 and 2 has advantages, when breakdown of the zener diode 220 occurs, the current is distributed over the entire interface of the N+ implant 130 and the sinker region 120, as shown by the arrows in FIG. 1, and breakdown typically begins at the sidewalls of the N+ implant 130, and not the bottom of the N+ implant 130. As such, with this breakdown profile, it takes longer for the zener device 220 to completely turn on, and does not provide a low resistance path to ground.

In U.S. Pat. No. 4,758,537, there exists a P− region 11 that will prevent lateral breakdown over an upper sidewall portion of the N++ region 11 as shown in FIG. 2 of that patent, but the P− region 11 will not prevent lateral breakdown of a lower sidewall portion of the N++ region 11, and as a result substantial lateral breakdown occurs.

The present invention attempts to provide a zener diode where the breakdown current is steered uniformly through the bottom wall of the diode in order to provider higher current handling and improved speed of operation.

### SUMMARY OF THE INVENTION

The present invention relates to an N+/P+ zener diode where the implanted regions are designed to steer the current flow away from the sidewalls of the diode and towards the bottom walls in order to induce uniform reverse breakdown, thereby leading to improved speed of operation and increase in current handling capability.

In one aspect, the present invention provides a method of operating a zener diode by initiating vertical breakdown of the zener diode between an implant region of one conductivity type and an implant region of an opposite conductivity type; and during the step of initiating vertical breakdown, inhibiting lateral breakdown of the zener diode between a sidewall of the implant region and an adjacent region.

In another aspect, the present invention provides a zener diode that has a substrate of one conductivity type; a sinker dopant region of the same conductivity type as the substrate, disposed above and electrically connected to the substrate; a dopant region disposed above the sinker dopant region, the dopant region having an opposite conductivity type as the substrate and the sinker dopant region, the dopant region further having sidewalls and a bottom, with the bottom contacting the sinker dopant region; and an epitaxial region, the epitaxial region surrounding the dopant region, thereby being adjacent to all sidewalls of the dopant region.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 illustrates in cross-sectional side view a prior art design and its electrical representation.

FIG. 2 illustrates a circuit diagram of the FIG. 1 design.

FIG. 3 illustrates in cross-sectional view of an embodiment of the present invention.

FIGS. 4(a)-(e) illustrate a flow diagram of the fabrication steps for forming the structure of FIG. 3.

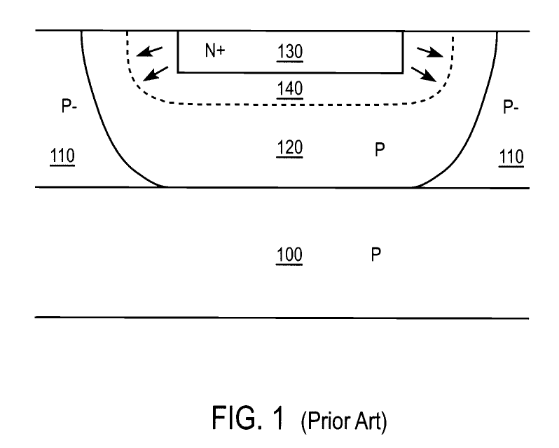

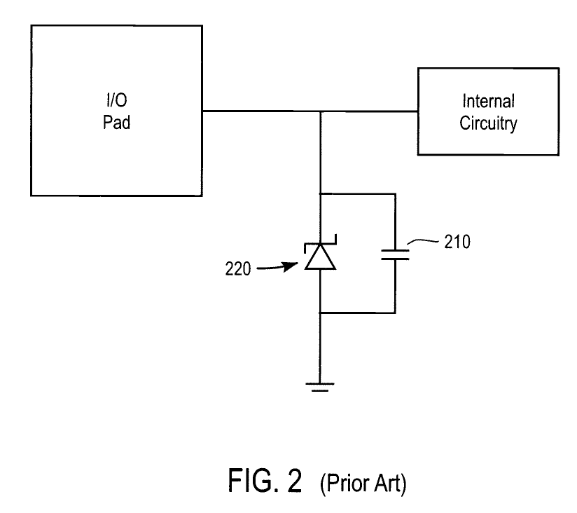

### DETAILED DESCRIPTION OF THE INVENTION

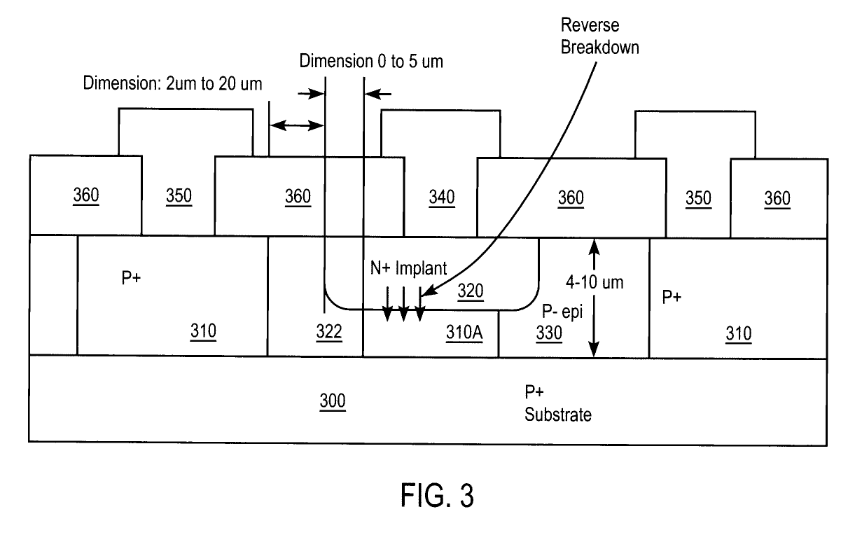

Referring first to FIG. 3, a first implementation of the invention is illustrated. The substrate 300 is formed of P+ doped material. Although this first implementation is described with respect to a P+ substrate, and layers corresponding thereto above this P+ substrate 300, it will be understood that the present invention can be implemented with an N+ substrate, and corresponding layers above, as is known in the art. A P− epitaxial layer 330 is grown over the P+ substrate. Within the epitaxial layer, a P+ sinker region 310 is created. Over a central region 310A of the sinker layer there is an N+ implant region 320. Surrounding the N+ implant 320, and extending below a bottom surface 322 of the N+ implant 320, is the P− epitaxial region 330 As shown, the portion of the P− epitaxial region adjacent to the N+ implant region has a width of X+Y, where the values of X and Y are determined based on the implant conditions, total thermal out diffusion, and photolithographic mask bias. In a typical arrangement the value of X can range from 0 to 5 um and the value of Y can range between 2 um to 20 um.

Contacts are made to the N+ and the P+ regions using standard semiconductor processing methods consisting of deposition and patterning of a dielectric film followed by etch, metal deposition and patterning. The metal 340 contact to the N+ layer serves as the anode of the device. The metal 350 contact to the P+ layer serves as the cathode of the device.

Due to the existence of the P+ sinker 310A and the P− epitaxy 330 that surrounds the N+ implant 320, the reverse breakdown will occur vertically, and only from the bottom surface of the N+ implant 320 that interfaces with a top surface of the central region 310A of the P+ sinker 310. This is schematically illustrated by the vertical arrows.

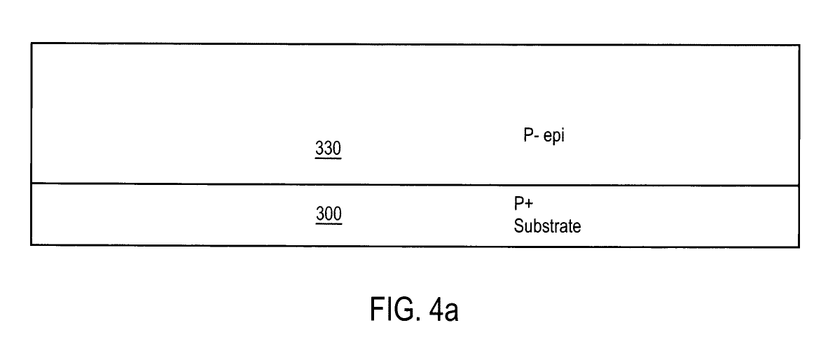

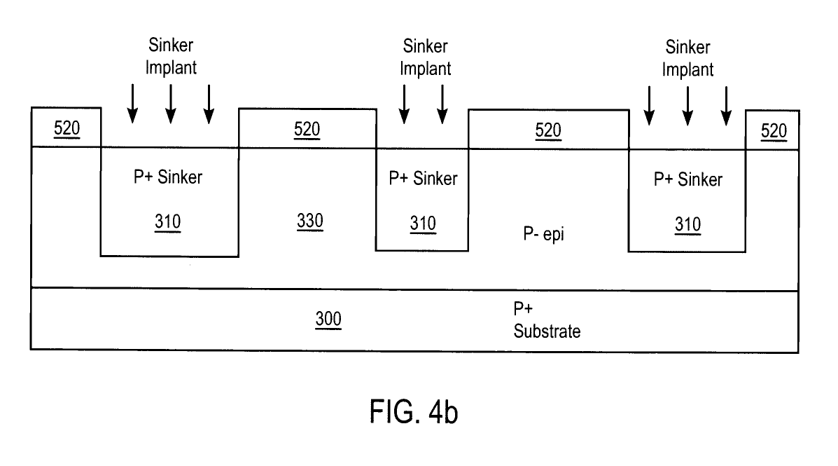

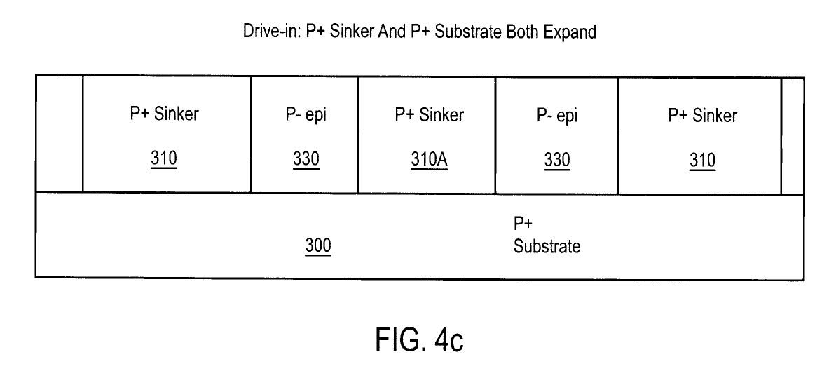

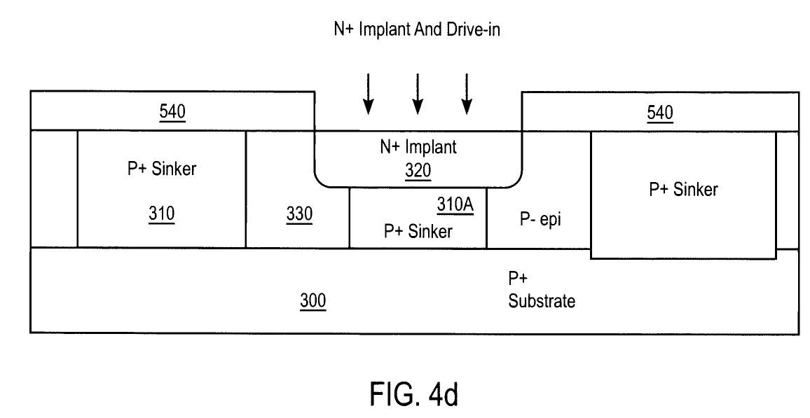

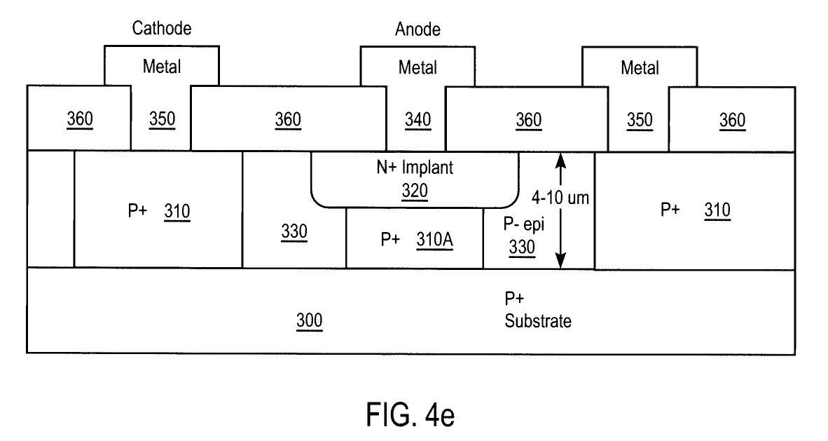

FIGS. 4(a)-4e) illustrate fabrication steps for the device illustrated in FIG. 3. It is understood that the overall process steps are described, and that one of ordinary skill will understand certain specific steps needed in order to execute them.

FIG. 4(a) illustrates a starting point, in which a P− epitaxial layer 330 has already been grown over a P+ substrate 300. Next, in FIG. 4(b), there is shown a mask 520 that is used so that a P+ sinker regions 310 can be implanted into the P− epitaxial layer 330. After implantation and thermal drive-in the resulting structure is shown in FIG. 4(c). The P+ sinker regions 310 and the P+ substrate 300 out diffuse and connect to each other, leaving the P− epitaxial region 330, which surrounds the central sinker region 310A.

FIG. 4(d) illustrates formation of a mask layer 540, which is then used to allow for the selective implantation of N+ region 320, which through annealing is then driven to the appropriate depth, so that the bottom of the N+ region 320 contacts the P+ sinker region 310A.

FIG. 4(e) illustrates the formation of the electrical connections, with the N+ and P+ regions forming the anode and the cathode

Thicknesses and doping of various layers described above can vary, as well as temperature and times for the annealing processes. In a specific embodiment that has been found advantageous, the P+ substrate is 8 to 15 mohm-cm in resistivity, the P-epi layer is 4 to 14 um thick with a typical resistivity of 10 ohm-cm. The concentration of the boron in the P+ layer is approximately between 1E18/cm3 to 7E18/cm3. The corresponding peak doping of the dopants in the N+ region is in between 1E19/cm3 to 1E20/cm3.

It will be appreciated from the foregoing that the structure of FIG. 3 can be fabricated using a simple and inexpensive process sequence, making the fabrication of the invention attractive for numerous applications

The breakdown voltage of the Zener diode, can be modified by adjusting the concentration of the N+ region 320 and the P+ type sinker 310A. By providing low series resistance, the device can sink high currents during an ESD event, thus protecting the circuit connected to this device.

Having fully described a preferred embodiment of the invention and various alternatives, those skilled in the art will recognize, given the teachings herein, that numerous alternatives and equivalents exist which do not depart from the invention. It is therefore intended that the invention not be limited by the foregoing description, but only by the appended claims.

We claim:

1. A method of operating a zener diode, the method comprising the steps of:
initiating vertical breakdown of the zener diode between an implant region of one conductivity type and an implant region and of an opposite conductivity type; and
during the step of initiating vertical breakdown, inhibiting lateral breakdown of the zener diode between a sidewall of the implant region and an adjacent region.

2. The method according to claim 1 wherein the step of inhibiting lateral breakdown includes the step of inhibiting breakdown of the zener diode at a bottom corner of the implant region.

3. A zener diode device comprising:
a substrate of one conductivity type;
a sinker dopant region of the same conductivity type as the substrate, disposed above and electrically connected to the substrate;
a dopant region disposed above the sinker dopant region, the dopant region having an opposite conductivity type as the substrate and the sinker dopant region, the dopant region further having sidewalls and a bottom, with the bottom contacting the sinker dopant region;
an epitaxial region, the epitaxial region surrounding the dopant region, thereby being adjacent to all sidewalls of the dopant region.

4. The zener diode according to claim 3 wherein the epitaxial region has a bottom that extends below a bottom of the dopant region.

5. The zener diode according to claim 3 wherein the epitaxial region overlaps with the dopant region to ensure that bottom corners of the dopant region are surrounded by the epitaxial region.

6. The zener diode according to claim 3 further including sinker regions disposed on a periphery of the epitaxial region.

7. A method for fabricating ESD protection in an integrated circuit comprising the steps of
providing a substrate 300 having a first dopant concentration and an epitaxial layer 330 thereon at a relatively lower dopant concentration,
forming by conventional semiconductor process, in the epitaxial layer, sinker dopant regions having a dopant concentration higher than the dopant concentration in the epitaxial layer and substantially the same dopant concentration as the first dopant concentration, wherein at least one of the sinker dopant regions is a central sinker dopant region,
causing the sinker dopant regions to be driven into electrical connection with the substrate, thereby also creating a lower doped region from remaining portions of the epitaxial layer that surrounds the central sinker dopant region;
forming, within the epitaxial region and over the central sinker dopant region, a dopant region of a characteristic opposite to the characteristic of the sinker dopant regions, wherein the dopant region has a bottom that does not extend to a bottom of the lower doped region,
forming a metal layer over the dopant region, and
providing contacts to the metal layer and the substrate such that a Zener diode is formed that has only a vertical breakdown without any lateral breakdown.
